(19) United States
(12) Patent Application Publication
(10) Pub. No.: US 2026/0282233 A1
(43) Pub. Date: Sep. 17, 2026

(54) TECHNOLOGIES FOR PRINTED CIRCUIT BOARD LAYOUT FOR DIRECTLY PARALLELED ELECTRONIC DEVICES

(71) Applicant: Cornell University, Ithaca, NY (US)

(72) Inventors: Dheeraj Etta, Ithaca, NY (US); Sounak Maji, Sunnyvale, CA (US); Khurram Afridi, Ithaca, NY (US)

(21) Appl. No.: 19/566,484

(22) Filed: Mar. 13, 2026

Related U.S. Application Data
(60) Provisional application No. 63/772,389, filed on Mar. 14, 2025.

(51) Int. Cl. H05K 1/181; H02M 7/5387; H05K 1/11

(52) U.S. Cl. CPC H05K 1/181; H05K 1/115; H02M 7/5387; H05K 2201/10545

(57) ABSTRACT

Technologies for directly paralleled electronic devices include an electronic device with a substrate, such as a printed circuit board (PCB), having a top surface and a bottom surface. One or more semiconductor devices such as transistors, diodes, thyristors, or other power electronics are coupled to the top surface of the substrate, and another group of one or more semiconductor devices are coupled to the bottom surface. The substrate further includes conductive traces electrically coupled to terminals of the semiconductor devices and electrically coupled together by through-layer vias. The substrate includes planar layers stacked vertically, and the conductive traces and semiconductor devices on the top surface and the bottom surface are coextensive when viewed from above the substrate. The device may be a half-bridge inverter or a full-bridge inverter. Other embodiments are described and claimed.

### CROSS-REFERENCE TO RELATED APPLICATIONS

This application claims the benefit of and priority to U.S. Patent Application No. 63/772,389, entitled “LAYOUT FOR DIRECTLY PARALLELING DEVICES,” which was filed on Mar. 14, 2025, and which is incorporated herein by reference in its entirety.

### STATEMENT REGARDING FEDERALLY SPONSORED RESEARCH

This invention was made with government support under DE-AR0001572 awarded by the U.S. Department of Energy. The Government has certain rights in the invention.

### BACKGROUND

High-frequency inverters (e.g., inverters operating at multiple megahertz (MHz)) are used in high-frequency power electronics applications such as wireless power transfer, plasma generation, and resonant power conversion. Increasing the power capability of these inverters is challenging due to the limitations in available semiconductor devices, particularly their dynamic on-resistance and output capacitance characteristics at high frequencies. Paralleling transistors is a viable approach to enhance power handling, but conventional PCB layouts introduce imbalances in current sharing due to asymmetries in parasitic inductances and gate drive paths, leading to reliability concerns and increased losses.

### SUMMARY

According to one aspect of the disclosure, an electronic device includes a substrate having a top surface and a bottom surface, a first semiconductor device coupled to the top surface of the substrate, and a second semiconductor device coupled to the bottom surface of the substrate. The substrate further includes a first layer and a second layer. The first layer includes a first conductive trace electrically coupled to a first terminal of the first semiconductor device, and the second layer includes a second conductive trace electrically coupled to a first terminal of the second semiconductor device. The substrate further includes a plurality of through-layer vias that electrically couple the first conductive trace and the second conductive trace. The first layer and the second layer comprise planar layers stacked vertically. The first conductive trace and the second conductive trace are coextensive when viewed from above the substrate, and the first semiconductor device and the second semiconductor device are coextensive when viewed from above the substrate.

In an embodiment, the first layer further includes a third conductive trace electrically coupled to a second terminal of the first semiconductor device, and the second layer further includes a fourth conductive trace electrically coupled to a second terminal of the second semiconductor device. The substrate further includes a plurality of through-layer vias that electrically couple the third conductive trace and the fourth conductive trace. The third conductive trace and fourth conductive trace are coextensive when viewed from above the substrate. In an embodiment, the electronic device comprises a half-bridge inverter. The first semiconductor device and the second semiconductor device are transistors that collectively form a first switch of the half-bridge inverter. In an embodiment, a horizontal distance between the first semiconductor device and the second semiconductor device to the plurality of through-layer vias is determined based on a target voltage or current of the electronic device.

In an embodiment, the first layer comprises the top surface of the substrate, and the second layer comprises the bottom surface of the substrate. In an embodiment, the substrate further includes a third layer coupled between the first layer and the second layer. The third layer comprises a ground plane electrically coupled to the first semiconductor device and the second semiconductor device. In an embodiment, the substrate further includes a third layer coupled between the first layer and the second layer, and a fourth layer couped between the first layer and the second layer. The third layer comprises a ground plane electrically coupled to the first semiconductor device, and the fourth layer comprises a ground plane electrically coupled to the second semiconductor device. In an embodiment, the substrate further includes a fifth layer and a sixth layer coupled between the third layer and the fourth layer. In an embodiment, the fifth layer and the sixth layer comprise signaling traces.

In an embodiment, the substrate further comprises a plurality of layers coupled between the first layer and the second layer.

In an embodiment, each of the first semiconductor device and the second semiconductor device comprises a semiconductor power electronics device. In an embodiment, each of the first semiconductor device and the second semiconductor device comprises a diode, a transistor, or a thyristor. In an embodiment, each of the first semiconductor device and the second semiconductor device comprises a GaN device, a Si device, a SiC device, a Ga2O3 device, an AlN device, or a diamond device.

In an embodiment, each of the first layer and the second layer comprises a dielectric material, and wherein each of the first conductive trace and the second conductive trace comprises a metallic material. In an embodiment, the dielectric material comprises FR4 or a low-loss dielectric material. In an embodiment, the metallic material comprises copper, aluminum, silver, or gold.

In an embodiment, the first layer comprises a first geometric bounds and the second layer comprises a second geometric bounds, and wherein at least 80% of the first geometric bounds match the second geometric bounds. In an embodiment, at least 90% of the first geometric bounds match the second geometric bounds.

In an embodiment, the first semiconductor device is located at a first position on the substrate. The first position is defined by a pair of imaginary orthogonal axes that are parallel to the top surface of the substrate. The second semiconductor device is located at a second position on the substrate defined by the pair of imaginary orthogonal axes. The second position is within a predetermined threshold distance from the first position.

In an embodiment, the electronic device further comprises a first full-bridge inverter, a second full-bridge inverter, and a power-combining network coupled to the printed circuit board. The first semiconductor device and the second semiconductor device are transistors that collectively form a first switch of the first full-bridge inverter. The power-combining network comprises a first transformer and a second transformer. A primary winding of the first transformer is coupled to the first full-bridge inverter and a primary winding of the second transformer is coupled to the second full-bridge inverter. A secondary winding of the first transformer and a secondary winding of the second transformer are coupled in series. In an embodiment, each of the first transformer and the second transformer are 1:1 air-core transformers.

### BRIEF DESCRIPTION OF THE DRAWINGS

The concepts described herein are illustrated by way of example and not by way of limitation in the accompanying figures. For simplicity and clarity of illustration, elements illustrated in the figures are not necessarily drawn to scale. Where considered appropriate, reference labels have been repeated among the figures to indicate corresponding or analogous elements.

FIG. 1 is a top view of at least one embodiment of a multi-layer device with symmetric parallel electronic devices;

FIG. 2 is a bottom view of the device of FIG. 1;

FIG. 3 is a top view of at least one embodiment of a multi-layer device with symmetric parallel electronic devices including a half-bridge inverter;

FIG. 4 is a bottom view of the device of FIG. 3;

FIG. 5 is a cross-sectional schematic view of the device of FIGS. 3-4;

FIG. 6 is an electrical schematic view of the device of FIGS. 3-5;

FIG. 7 is a cross-sectional schematic view of a multi-layer device similar to the device of FIGS. 3-4 and having two layers;

FIG. 8 is a cross-sectional schematic view of a multi-layer device similar to the device of FIGS. 3-4 and having three layers;

FIG. 9 is a cross-sectional schematic view of a multi-layer device similar to the device of FIGS. 3-4 and having four layers;

FIG. 10 is a cross-sectional schematic view of a multi-layer device similar to the device of FIGS. 3-4 and having more than four layers;

FIG. 11 is a top view of at least one embodiment of a multi-layer device with symmetric parallel electronic devices including a full-bridge inverter;

FIG. 12 is a bottom view of the device of FIG. 11;

FIG. 13 is an electrical schematic view of the device of FIGS. 11-12;

FIG. 14 is a top view of at least one embodiment of a device incorporating multiple full-bridge inverters similar to the device of FIGS. 11-13; and

FIG. 15 is a schematic diagram of the device of FIG. 14 coupled to a power combining network.

### DETAILED DESCRIPTION OF THE DRAWINGS

While the concepts of the present disclosure are susceptible to various modifications and alternative forms, specific embodiments thereof have been shown by way of example in the drawings and will be described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

References in the specification to “one embodiment,” “an embodiment,” “an illustrative embodiment,” etc., indicate that the embodiment described may include a particular feature, structure, or characteristic, but every embodiment may or may not necessarily include that particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described. Additionally, it should be appreciated that items included in a list in the form of “at least one A, B, and C” can mean (A); (B); (C); (A and B); (A and C); (B and C); or (A, B, and C). Similarly, items listed in the form of “at least one of A, B, or C” can mean (A); (B); (C); (A and B); (A and C); (B and C); or (A, B, and C).

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features.

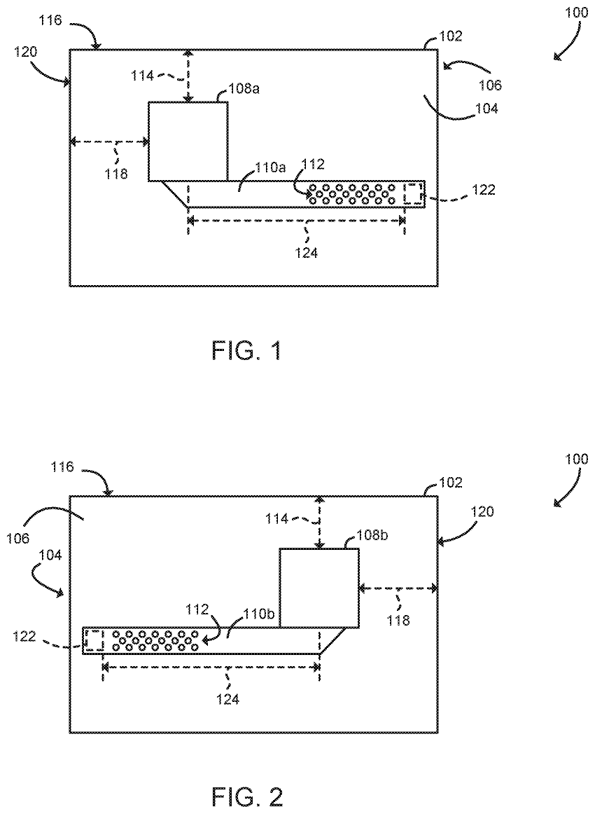

Referring now to FIGS. 1-2, one potential embodiment of a device 100 with symmetric parallel electronic devices includes a multi-layer substrate 102 with a top surface 104 and a bottom surface 106. A pair of semiconductor devices 108a, 108b, such as transistors or other power electronics devices, are attached to the respective surfaces 104, 106. Each semiconductor device 108a, 108b is coupled to a respective conductive trace 110a, 110b positioned on the respective surface 104, 106, and those conductive traces 110a, 110b are connective by one or more through-layer vias 112. Accordingly, the semiconductor devices 108a, 108b are thereby electrically connected in parallel. As described further below, the layout of each surface 104, 106, including the positions of the devices 108a, 108b and associated conductive traces 110a, 110b are symmetrical, such that the devices 108a, 108b and the conductive traces 110a, 110b are aligned with each other.

Accordingly, the disclosed device 100 facilitates the direct paralleling of two GaN transistors or other transistors, for example in a full-bridge inverter operating at multi-MHz frequencies. As compared to conventional designs that lay out paralleled semiconductor devices side-by-side on the same PCB layer, the disclosed design ensures balanced current sharing between transistors, significantly enhancing power handling capability and system efficiency. Further, by leveraging a six-layer PCB structure, the disclosed layout optimizes gate drive symmetry, minimizes parasitic effects, and improves thermal performance. Additionally, the disclosed device 100 may use vias to connect switch nodes between layers, ensuring minimal impedance mismatch. As another example, the disclosed device 100 may route pulse width modulation (PWM) signals with equal trace lengths to the paralleled transistors to prevent timing skew. While particularly well-suited for high-power, high-frequency applications such as wireless power transfer and plasma generation, the disclosed layout is adaptable to various semiconductor device technologies and packaging footprints, extending its applicability beyond GaN-based systems.

The disclosed device 100 may provide increased power capability at multi-MHz frequencies as compared to existing approaches for paralleling transistors, for example by removing imbalances in current sharing due to asymmetries in parasitic inductances and gate drive paths, thereby improving reliability and reducing losses in the disclosed device 100. Accordingly, the disclosed device 100 may be used for high-frequency power electronics applications such as wireless power transfer, plasma generation, and resonant power conversion.

As another advantage, the disclosed device 100 may provide proper current balancing between devices without requiring additional circuity for paralleling, particularly in the multi-MHz range. For example, the disclosed device 100 may support multi-MHz power electronics applications by directly paralleling transistors, and without requiring parallel-in, series-out transformers, immittance networks, or other additional circuitry to mitigate the need for direct transistor paralleling.

Accordingly, the disclosed technologies provide multiple advantages or conventional approaches. For example, the disclosed technologies may provide optimized power device placement. Unlike conventional approaches that position the two paralleled power semiconductor devices side by side on the same PCB layer, the proposed layout places one device on the top layer and the other on the bottom layer, with their footprints precisely aligned or aligned within a predetermined tolerance. This configuration ensures symmetric current distribution, minimizing imbalances and enhancing performance.

As another example, the disclosed technologies may provide a symmetric gate drive path. The disclosed layout maintains equal propagation delay for both transistors, effectively reducing parasitic gate impedance and improving switching performance.

As another example, the disclosed technologies may provide a layered architecture for device paralleling. Illustratively, a six-layer PCB structure is employed, incorporating dedicated power and ground planes to mitigate common-mode noise and inductance, thereby enhancing overall system stability.

As another example, the disclosed technologies may provide optimized parasitic inductance distribution. The disclosed design carefully controls parasitic inductances to facilitate efficient high-frequency operation without compromising switching performance or increasing losses.

As another example, the disclosed technologies may provide scalability across semiconductor technologies. While specifically described in connection with GaN transistors, the disclosed layout is adaptable to other semiconductor technologies, such as SiC MOSFETs and high-speed power devices, broadening its applicability across various power electronics applications.

Referring again to FIG. 1, a top view of the substrate 102 shows the top surface 104. The substrate 102 may be embodied as an insulating material including one or more layers. The substrate 102 may be formed from a fiberglass material, polyimide or other flexible circuit board material, ceramic, or other insulating material. The illustrative substrate 102 is a multi-layer printed circuit board (PCB), with each layer formed from a dielectric material such as FR4, a low-loss dielectric material, or another circuit board material. The illustrative substrate 102 includes six layers; however, as described and illustrated further below, in other embodiments the substrate 102 may have a different number of layers. In the illustrative embodiment, the substrate 102 is manufactured using high-quality PCB fabrication techniques ensuring low parasitic inductance. In some embodiments, thermal management may be optimized by leveraging multi-layer copper pours for heat dissipation.

The illustrative substrate 102 includes a semiconductor device 108a mounted, attached, or otherwise coupled to the surface 104. The device 108a may be embodied as a power electronics device, such as a transistor, a diodes, a thyristor, or other power electronics device. Additionally or alternatively, in some embodiments the device 108a may be embodied as an embedded gate driver, optical isolator, or other electronic component coupled to the surface 104. As described above, embedded gate drivers included close to the transistors may be used to minimize propagation delays. The semiconductor device 108a may be formed using one or more semiconductor materials, such as gallium nitride (GaN), silicon (Si), silicon carbide (SiC), gallium(III) oxide (Ga₂O₃), aluminum nitride (AlN), diamond, or another material. Additionally or alternatively, although illustrated as including a single device 108a coupled to the top surface 104, it should be understood that in some embodiments multiple devices 108 may be coupled to the top surface 104.

As shown, the substrate 102 further includes a conductive trace 110a positioned on or otherwise coupled to the top surface 104. The conductive trace 110a is illustratively formed from a metallic material such as copper (Cu), aluminum (Al), silver (Ag), or gold (Au). The conductive trace 110a may be electrically connected to one or more terminals of the semiconductor device 108a. For example, when the device 108a is a transistor, the conductive trace 110a may be electrically connected to a source terminal, drain terminal, gate terminal, or other terminal of the device 108a. Accordingly, although illustrated as including a single conductive trace 110a coupled to the top surface 104, it should be understood that the substrate 102 may include multiple conductive traces 110 positioned on the top surface 104.

Referring now to FIG. 2, a bottom view of the substrate 102 shows the bottom surface 106. Similar to the top surface 104 shown in FIG. 1, the substrate 102 includes a semiconductor device 108b mounted, attached, or otherwise coupled to the surface 106. As described further below, the semiconductor device 108b may be embodied as a power electronics device of the same type, model, or other specification as the semiconductor device 108a. In many embodiments, the semiconductor devices 108a, 108b are electrically connected in parallel as described further below. As shown, the substrate 102 further includes a conductive trace 110b positioned on or otherwise coupled to the bottom surface 106. The conductive trace 110b is similar to the conductive trace 110a and thus may be electrically connected to one or more terminals of the semiconductor device 108b.

The substrate 102 further includes one or more through-layer vias 112 that electrically connect the conductive traces 110a, 110b. Each of the vias 112 may be embodied as a metallic material, doped semiconductor, or other conductive material. Accordingly, by being connected by the vias 112, the conductive traces 110a, 110b form part of the same electrical node. As described further, the conductive traces 110a, 110b may operate as an output node, a gate signal, or other electrical node for the device 100. In some embodiments, a horizontal distance along the conductive trace 110a, 110b between the semiconductor device 108a, 108b and the vias 112 is determined based on a target voltage or current of the electronic device 100.

As shown in FIGS. 1 and 2, the layout of the substrate 102 on each surface 104, 106 is symmetric. That is, the positions of the semiconductor devices 108a, 108b and the outlines of the conductive traces 110a, 110b are symmetrical. Put another way, when viewed from above the substrate 102, the semiconductor devices 108a, 108b are coextensive, and the conductive traces 110a, 110b are also coextensive. For example, as shown in FIG. 1, the device 108a is positioned on the top surface 104 at a vertical distance 114 from an edge 116 of the substrate 102 and a horizontal distance 118 from another edge 120 of the substrate 102. Accordingly, the distances 114, 118 may define a location of the semiconductor device 108a on the substrate 102 in terms of a pair of imaginary orthogonal axes (e.g., an x-axis and a y-axis or other rectilinear coordinate system). As shown in FIG. 2, the device 108b is positioned on the bottom surface 106 at the vertical distance 114 from the edge 116 and the horizontal distance 118 from the edge 120. Accordingly, when viewed from the top, the device 108a is positioned directly over the device 108b; that is, the devices 108a, 108b are coextensive. The extents of the conductive traces 110a, 110b may be similarly defined in terms of imaginary orthogonal axes or otherwise defined.

Referring again to FIGS. 1 and 2, a portion 122 of the conductive trace 110a and/or the conductive trace 110b may be defined as a pad, a land, or other portion that may be used for connecting the respective trace 110a, 110b to a wire, a connector, or otherwise electrically connecting the trace 110a, 110b to another component. The portion 122 of either one of the traces 110a, 110b and/or both of the traces 110a, 110b may be used to connect to another component; as described above, the traces 110a, 110b are connected electrically by the vias 112.

As shown in FIG. 1, the device 108a is separated from the portion 122 of the trace 110a by a distance 124. The illustrative distance 124 extends to a halfway point of the device 108a; however, in other embodiments, the distance 124 may extend to a particular terminal, pin, or other location on the device 108a. As shown in FIG. 2, the device 108b is similarly separated from the portion 122 of the trace 110b by the same distance 124. This distance 124 may extend to a corresponding terminal pin, or other location on the device 108b. By including the same distance 124 between a connection portion 122 and each of the devices 108a, 108b, the illustrative device 100 may provide symmetric current distribution, provide equal propagation delay for each device 108a, 108b, reduce parasitic impedance, improve switching performance, or otherwise improve performance of the device 100.

Although illustrated as being precisely symmetrical, it should be understood that in some embodiments the top side 104 and the bottom side may be symmetrical within certain tolerances. For example, each device 108a, 108b may be located at the same position within a predetermined threshold distance. As another example, the geometric bounds (e.g., position, coordinates, outlines, or other geometric extents) of each layer 104, 106 may match within a certain percentage, such as 80%, 90%, or another threshold.

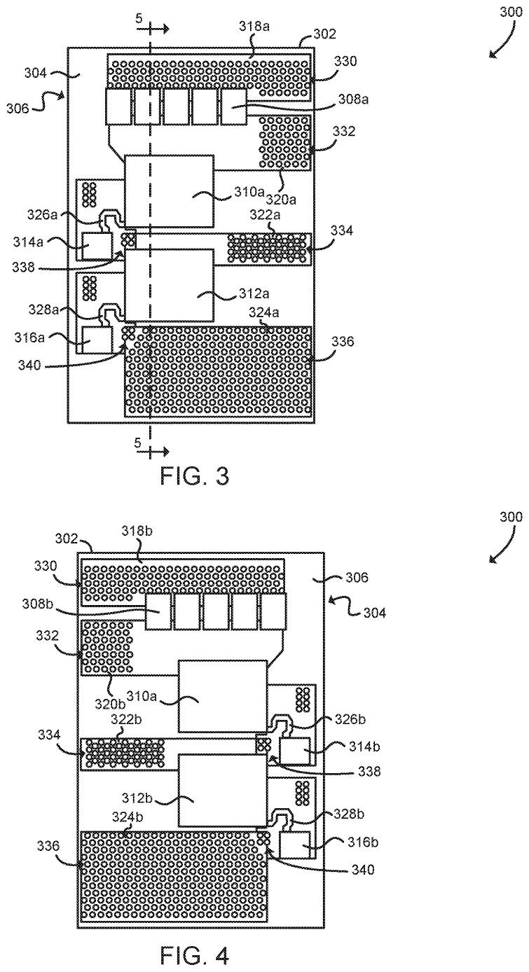

Referring now to FIGS. 3-5, another potential embodiment of a device 300 with symmetric parallel electronic devices includes a printed circuit board (PCB) 302 with a top surface 304 and a bottom surface 306, similar to the substrate 102 of FIGS. 1-2. The illustrative device 300 is a half-bridge inverter. As described further below, the illustrative device 300 includes pairs of semiconductor devices positioned on the surfaces 304, 306 and connected in parallel, which collectively each form a switch of the half-bridge inverter.

Referring to FIG. 3, a top view of the PCB 302 shows the top surface 304. Multiple capacitors 308a are attached to the top surface 304. The capacitors 308 may be embodied as decoupling capacitors, which may mitigate voltage spikes and electromagnetic interference (EMI).

Semiconductor devices 310a, 312a are further attached to the top surface 304. Each of the semiconductor devices 310a, 312a is illustratively a GaN power transistor; of course, in other embodiments, the semiconductor devices 310a, 312a may be embodied as transistors or other power electronics using other semiconductor material. Gate drivers 314a, 316a are further attached to the top surface 304. It should be understood that some embodiments, the device 300 may include additional discrete or integrated electronic components such as optical isolators or other components.

The PCB 302 further includes a conductive trace 318a that is electrically connected to the capacitors 308a. The trace 318a may be connected, for example, to a positive DC supply voltage for the PCB 302 (not shown). The PCB 302 further includes a conductive trace 320a that connects the capacitors 308a to the transistor 310a. Illustratively, the conductive trace 320a is connected to the source terminal of the transistor 310a. The PCB 302 further includes a conductive trace 322a that connects the transistors 310a, 312a. Illustratively, the trace 322a is connected to the drain terminal of the transistor 310a and to the source terminal of the transistor 312a. As described further below in connection with FIG. 6, the trace 322a is at the output node of the half-bridge inverter formed by the device 300. The PCB 302 further includes a conductive trace 324a connected to the transistor 312a. Illustratively, the trace 324a connects the drain terminal of the transistor 312a to a negative DC supply voltage for the PCB 302 (not shown) and/or to ground. The PCB 302 further includes a conductive trace 326a that connects the gate driver 314a to the transistor 310a (i.e., to a gate terminal of the transistor 310a), and a conductive trace 328a that connects the gate driver 316a to the transistor 312a (i.e., to a gate terminal of the transistor 312a).

Referring now to FIG. 4, a bottom view of the PCB 302 shows the bottom surface 306. As shown, the bottom surface 306 includes a symmetric layout to the top surface 304. Accordingly, multiple capacitors 308b are attached to the bottom surface 306, similar to the capacitors 308a attached to the top surface 104.

Semiconductor devices 310b, 312b are further attached to the bottom surface 306. Each of the semiconductor devices 310b, 312b is illustratively a GaN power transistor corresponding to the respective devices 310a, 312a attached to the top surface 104. Of course, in other embodiments, the semiconductor devices 310b, 312b may be embodied as transistors or other power electronics using other semiconductor material. Gate drivers 314b, 316b are further attached to the bottom surface 306.

The PCB 302 further includes a conductive trace 318b that is electrically connected to the capacitors 308b. The trace 318b may be connected, for example, to a positive DC supply voltage for the PCB 302 (not shown). The PCB 302 further includes a conductive trace 320b that connects the capacitors 308b to the transistor 310b. Illustratively, the conductive trace 320b is connected to the source terminal of the transistor 310b. The PCB 302 further includes a conductive trace 322b that connects the transistors 310b, 312b. Illustratively, the trace 322b is connected to the drain terminal of the transistor 310b and to the source terminal of the transistor 312b. As described further below in connection with FIG. 6, the trace 322b is at the output node of the half-bridge inverter formed by the device 300. The PCB 302 further includes a conductive trace 324b connected to the transistor 312b. Illustratively, the trace 324b connects the drain terminal of the transistor 312b to a negative DC supply voltage for the PCB 302 (not shown) and/or to ground. The PCB 302 further includes a conductive trace 326b that connects the gate driver 314b to the transistor 310b (i.e., to a gate terminal of the transistor 310b), and a conductive trace 328b that connects the gate driver 316b to the transistor 312b (i.e., to a gate terminal of the transistor 312b).

Referring again to FIGS. 3-5, through-layer vias connect traces of the top surface 104 and the bottom surface 106. Illustratively, vias 330 connect the traces 318a, 318b; vias 332 connect the traces 320a, 320b; vias 334 connect the traces 322a, 322b; and vias 336 connect the traces 324a, 324b. Similarly, in some embodiments vias 338 may connect the traces 326a, 326b, and vias 340 may connect the traces 328a, 328b.

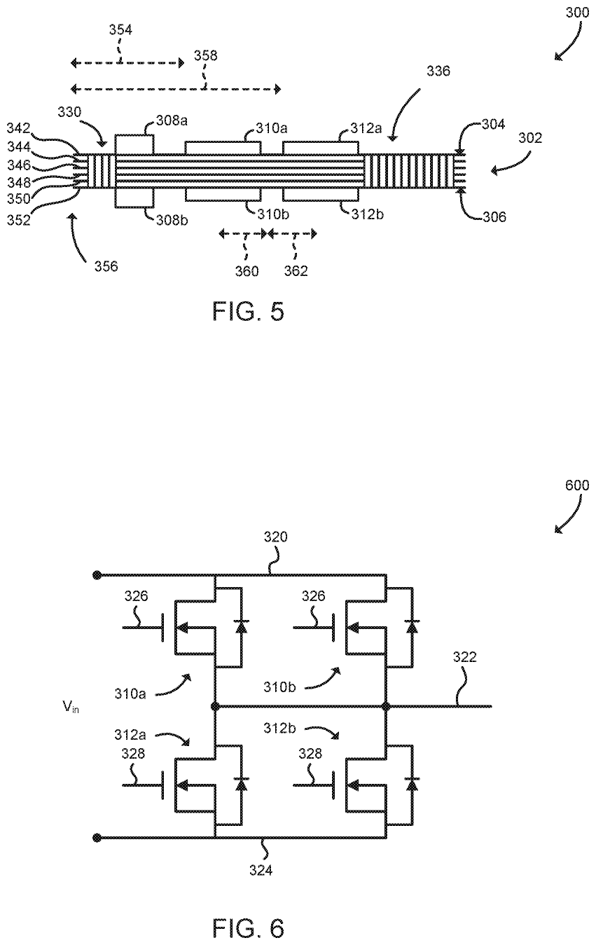

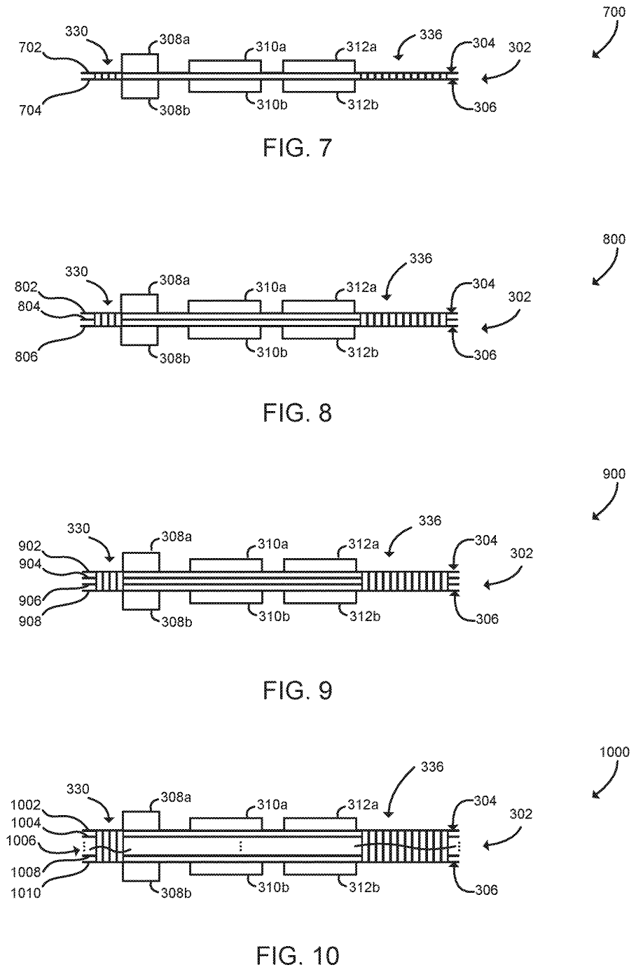

Referring now to FIG. 5, a cross-sectional view of the device 300 shows that the PCB 302 includes six layers 342, 344, 346, 348, 350, 352. As shown, the layer 342 includes the top surface 304, and the layer 352 includes the bottom surface 306. Interior layers 344, 346, 348, 350 are positioned between the layers 342, 352, and may include ground planes, signal traces, and/or other components. In the illustrative embodiment, the layer 344 is a ground plane electrically coupled to electrical devices on the top surface 304 (such as the transistors 310a, 312a), and the layer 350 is a ground plane electrically coupled to electrical devices on the bottom surface 306 (such as the transistors 310b, 312b). Continuing the illustrative embodiment, each of the layers 346, 348 includes signaling traces. Of course, different numbers and/or arrangements of layers are possible in other embodiments. Potential embodiments of other multi-layer PCBs 302 are illustrated in FIGS. 7-10 and described further below.

As described above, both the top surface 304 and the bottom surface 306 of the board 302 have symmetric layouts. Accordingly, as shown in FIG. 5, both of the transistors 310a, 310b are positioned at a same distance 354 from an edge 356 of the PCB board 302. Similarly, both of the transistors 312a, 312b are positioned at a same distance 358 from the edge 356 of the PCB board 302. Additionally, both of the transistors 310a, 310b are positioned at a same distance 360 from an output circuit node 322 (e.g., the traces 322a, 322b), and both of the transistors 312a, 312b are positioned at a same distance 362 from the output circuit node 322. Although illustrated in FIG. 5 as being between the centers of the respective devices 310a, 310b and the node 322, it should be understood that the distance 360 may be measured between any terminal or other part of the respective devices 310a, 310b and the node 322. Similarly, the distance 362 may also be measured between any terminal or other part of the respective devices 312a, 312b and the node 322.

Referring now to FIG. 6, schematic diagram 600 illustrates the half-bridge inverter formed by the device 302. The diagram 600 illustrates circuit node 320, which represents the traces 320a, 320b coupled by the vias 332. Similarly, the diagram 600 further illustrates circuit nodes 322, 324, 326, 328, which similarly represent respective traces on both surfaces 304, 306 of the board 302 that are electrically connected by respective vias 334, 336, 338, 340. As shown, the circuit nodes 320, 324 are coupled to a DC input voltage Vᵢₙ. The transistors 310a, 310b are coupled in parallel between the nodes 320, 322, and the transistors 312a, 312b are coupled in parallel between the nodes 322, 324. The gates of the transistors 310a, 310b are coupled to the node 326, and the gates of the transistors 312a, 312b are coupled to the node 328. The node 322 is the output node of the half-bridge inverter. Accordingly, each of the parallel transistors 310a, 310b collectively forms a switch of the half-bridge inverter, and each of the parallel transistors 312a, 312b collectively forms another switch of the half-bridge inverter.

Referring now to FIG. 7, a cross-sectional view of a device 700 illustrates a multi-layer device 700 with components similar to the device 300 of FIGS. 3-5, the description of which is also applicable to the device 700. The illustrative PCB 302 shown in FIG. 7 includes two layers 702, 704. As shown, the layer 702 includes the top surface 304, and the layer 704 includes the bottom surface 306. The device 700 does not include interior layers.

Referring now to FIG. 8, a cross-sectional view of a device 800 illustrates a multi-layer device 800 with components similar to the device 300 of FIGS. 3-5, the description of which is also applicable to the device 800. The illustrative PCB 302 shown in FIG. 8 includes three layers 802, 804, 806. As shown, the layer 802 includes the top surface 304, and the layer 806 includes the bottom surface 306. The interior layer 804 is positioned between the layers 802, 806. The interior layer 804 illustratively includes a ground plane, which may be electrically coupled to electrical devices on both surfaces 304, 306 of the PCB 302 (e.g., the devices 310a, 310b, 312a, 312b).

Referring now to FIG. 9, a cross-sectional view of a device 900 illustrates a multi-layer device 900 with components similar to the device 300 of FIGS. 3-5, the description of which is also applicable to the device 900. The illustrative PCB 302 shown in FIG. 9 includes four layers 902, 904, 906, 908. As shown, the layer 902 includes the top surface 304, and the layer 908 includes the bottom surface 306. Interior layers 904, 906 are positioned between the layers 902, 908. In the illustrative embodiment, the layer 904 is a ground plane electrically coupled to electrical devices on the top surface 304 (such as the transistors 310a, 312a), and the layer 906 is a ground plane electrically coupled to electrical devices on the bottom surface 306 (such as the transistors 310b, 312b).

Referring now to FIG. 10, a cross-sectional view of a device 1000 illustrates a multi-layer device 1000 with components similar to the device 300 of FIGS. 3-5, the description of which is also applicable to the device 1000. The illustrative PCB 302 shown in FIG. 10 includes five or more layers 1002, 1004, 1006, 1008, 1010. As shown, the layer 1002 includes the top surface 304, and the layer 1010 includes the bottom surface 306. Interior layers 1004, 1008 are positioned between the layers 1002, 1010, and one or more additional interior layers 1006 are positioned between the interior layers 1004, 1008. Each of the interior layers 1004, 1006, 1008 may include ground planes, signal traces, and/or other components as described above.

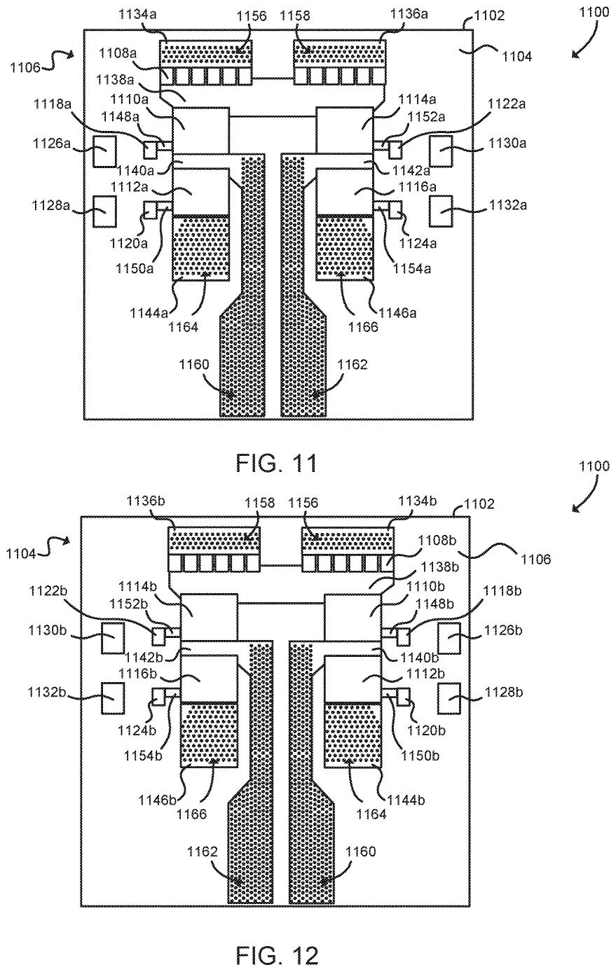

Referring now to FIGS. 11-12, another potential embodiment of a device 1100 with symmetric parallel electronic devices includes a printed circuit board (PCB) 1102 with a top surface 1104 and a bottom surface 1106, similar to the substrate 102 of FIGS. 1-2 and the PCB 302 of FIGS. 3-5. The illustrative device 1100 is a full-bridge inverter. As described further below, the illustrative device 1100 includes pairs of semiconductor devices positioned on the surfaces 1104, 1106 and connected in parallel, which collectively each form a switch of the full-bridge inverter.

Referring to FIG. 11, a top view of the PCB 1102 shows the top surface 1104. Multiple capacitors 1108a are attached to the top surface 1104. The capacitors 1108 may be embodied as decoupling capacitors, which may mitigate voltage spikes and electromagnetic interference (EMI).

Semiconductor devices 1110a, 1112a, 1114a, 1116a are further attached to the top surface 1104. Each of the semiconductor devices 1110a, 1112a, 1114a, 1116a is illustratively a 650 V GaN FET power transistor; of course, in other embodiments, the semiconductor devices 1110a, 1112a, 1114a, 1116a may be embodied as transistors or other power electronics using other semiconductor material. Gate drivers 1118a, 1120a, 1122a, 1124a and digital isolators 1126a, 1128a, 1130a, 1132a are further attached to the top surface 1104.

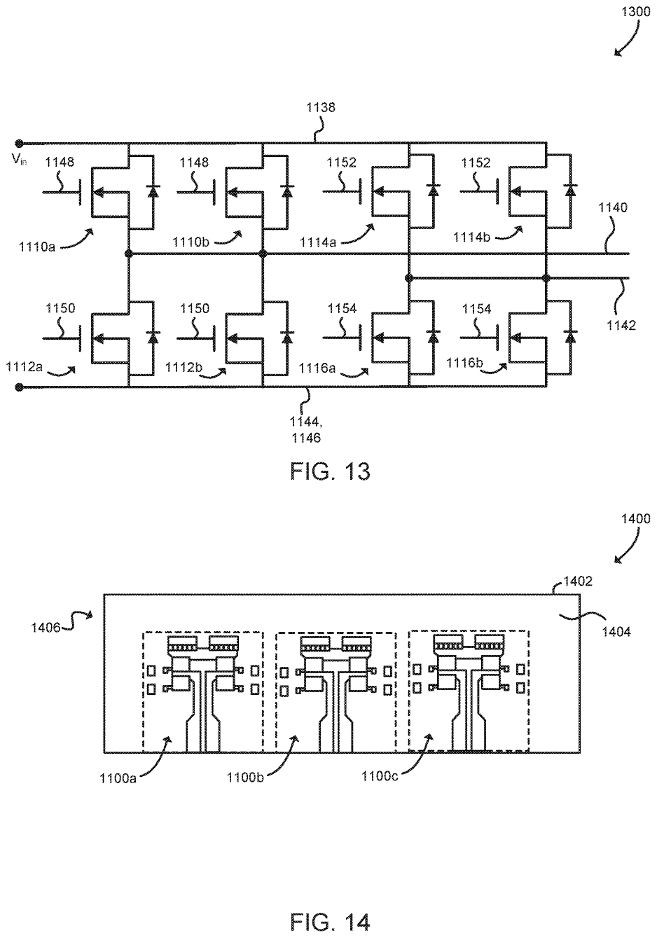

The PCB 1102 further includes conductive traces 1134a, 1136a that are electrically connected to the capacitors 1108a. Each of the trace 1134a, 1136a may be connected, for example, to a positive DC supply voltage for the PCB 1102 (not shown). The PCB 1102 further includes a conductive trace 1138a that connects the capacitors 1108a to the transistors 1110a and 1114a. Illustratively, the conductive trace 1138a is connected to the source terminal of each of the transistors 1110a, 1114a. The PCB 1102 further includes a conductive trace 1140a that connects the transistors 1110a, 1112a. Illustratively, the trace 1140a is connected to the drain terminal of the transistor 1110a and to the source terminal of the transistor 1112a. Similarly, the PCB 1102 includes a conductive trace 1142a that connects the transistors 1114a, 1116a. Illustratively, the trace 1142a is connected to the drain terminal of the transistor 1114a and to the source terminal of the transistor 1116a. As described further below in connection with FIG. 13, the traces 1140a, 1142a are at the output of the full-bridge inverter formed by the device 1100. The PCB 1102 further includes a conductive trace 1144a connected to the transistor 1112a. Illustratively, the trace 1144a connects the drain terminal of the transistor 1112a to a negative DC supply voltage for the PCB 1102 (not shown) and/or to ground. Similarly, the PCB 1102 includes a conductive trace 1146a connected to the transistor 1116a. Illustratively, the trace 1146a connects the drain terminal of the transistor 1116a to a negative DC supply voltage for the PCB 1102 (not shown) and/or to ground. Illustratively, the PCB 1102 further includes a conductive trace 1148a that connects the gate driver 1118a to the transistor 1110a (i.e., to a gate terminal of the transistor 1110a), a conductive trace 1150a that connects the gate driver 1120a to the transistor 1112a, a conductive trace 1152a that connects the gate driver 1122a to the transistor 1114a, and a conductive trace 1154a that connects the gate driver 1124a to the transistor 1116a. The PCB 1102 may include additional and/or different conductive traces in other embodiments.

Referring now to FIG. 12, a bottom view of the PCB 1102 shows the bottom surface 1106. As shown, the bottom surface 1106 includes a symmetric layout to the top surface 1104. Accordingly, multiple capacitors 1108b are attached to the bottom surface 1106.

Semiconductor devices 1110b, 1112b, 1114b, 1116b are further attached to the bottom surface 1106. Each of the semiconductor devices 1110b, 1112b, 1114b, 1116b is illustratively a GaN power transistor; of course, in other embodiments, the semiconductor devices 1110b, 1112b, 1114b, 1116b may be embodied as transistors or other power electronics using other semiconductor material. Gate drivers 1118b, 1120b, 1122b, 1124b and digital isolators 1126b, 1128b, 1130b, 1132b are further attached to the bottom surface 1106.

The PCB 1102 further includes conductive traces 1134b, 1136b that are electrically connected to the capacitors 1108b. Each of the trace 1134b, 1136b may be connected, for example, to a positive DC supply voltage for the PCB 1102 (not shown). The PCB 1102 further includes a conductive trace 1138b that connects the capacitors 1108b to the transistors 1110b and 1114b. Illustratively, the conductive trace 1138b is connected to the source terminal of each of the transistors 1110b, 1114b. The PCB 1102 further includes a conductive trace 1140b that connects the transistors 1110b, 1112b. Illustratively, the trace 1140b is connected to the drain terminal of the transistor 1110b and to the source terminal of the transistor 1112b. Similarly, the PCB 1102 includes a conductive trace 1142b that connects the transistors 1114b, 1116b. Illustratively, the trace 1142b is connected to the drain terminal of the transistor 1114b and to the source terminal of the transistor 1116b. As described further below in connection with FIG. 13, the traces 1140b, 1142b are at the output of the full-bridge inverter formed by the device 1100. The PCB 1102 further includes a conductive trace 1144b connected to the transistor 1112b. Illustratively, the trace 1144b connects the drain terminal of the transistor 1112b to a negative DC supply voltage for the PCB 1102 (not shown) and/or to ground. Similarly, the PCB 1102 includes a conductive trace 1146b connected to the transistor 1116b. Illustratively, the trace 1146b connects the drain terminal of the transistor 1116b to a negative DC supply voltage for the PCB 1102 (not shown) and/or to ground. Illustratively, the PCB 1102 further includes a conductive trace 1148b that connects the gate driver 1118b to the transistor 1110b (i.e., to a gate terminal of the transistor 1110b), a conductive trace 1150b that connects the gate driver 1120b to the transistor 1112b, a conductive trace 1152b that connects the gate driver 1122b to the transistor 1114b, and a conductive trace 1154b that connects the gate driver 1124b to the transistor 1116b. The PCB 1102 may include additional and/or different conductive traces in other embodiments.

Referring again to FIGS. 11 and 12, through-layer vias connect conductive traces of the top surface 1104 and the bottom surface 1106. Illustratively, vias 1156 connect the traces 1134a, 1134b; vias 1158 connect the traces 1136a, 1136b; vias 1160 connect the traces 1140a, 1140b; vias 1162 connect the traces 1142 a, 1142 b; vias 1164 connect the traces 1144 a, 1144 b; and vias 1166 connect the traces 1146a, 1146b. Similarly, in some embodiments, vias (not shown) may connect the respective traces 1148a, 1148b, 1150a, 1150b, 1152a, 1152b, 1154a, 1154b.

Referring now to FIG. 13, schematic diagram 1300 illustrates the full-bridge inverter formed by the device 1102. The diagram 1100 illustrates circuit node 1138, which represents the traces 1138a, 1138b coupled by vias. Similarly, the diagram 600 further illustrates circuit nodes 1140, 1142, 1144, 1146, 1148, 1150, 1152, 1154, which similarly represent respective traces on both surfaces 1104, 1106 of the board 1102 that are electrically connected by respective vias. As shown, the circuit node 1138 is coupled to one terminal of a DC input voltage Vᵢₙ, and circuit nodes 1144, 1146 (which are electrically connected) are coupled to an other terminal of the DC input voltage Vᵢₙ. The transistors 1110a, 1110b are coupled in parallel between the nodes 1138, 1140, and the transistors 1112a, 1112b are coupled in parallel between the nodes 1140, 1144. Similarly, the transistors 1114a, 1114b are coupled in parallel between the nodes 1138, 1142, and the transistors 1116a, 1116b are coupled in parallel between the nodes 1142, 1144. The gates of the transistors 1110a, 1110b are coupled to the node 1148, the gates of the transistors 1112a, 1112b are coupled to the node 1150, the gates of the transistors 1114a, 1114b are coupled to the node 1152, and the gates of the transistors 1116a, 1116b are coupled to the node 1154. The nodes 1140, 1142 are the output of the full-bridge inverter. Accordingly, each of the parallel transistors 1110a, 1110b collectively forms a switch, each of the parallel transistors 1112a, 1112b collectively forms a switch, each of the parallel transistors 1114a, 1114b collectively forms a switch, and each of the parallel transistors 1116a, 1116b collectively forms a switch of the full-bridge inverter.

In an experiment, a prototype device 1100 was constructed using 650 V GaN FETs connected directly in parallel in an full-bridge structure as described above. This full-bridge inverter 1100 was tested in a 6.78 MHz 12 cm air-gap capacitive wireless power transfer (WPT) system. While delivering 400 W of output power, it was delivered that current was equally shared between the paralleled transistors. The experimental device was capable of delivering up to a maximum of 3.95 kW of output power, which is nearly 1.9 times the output power achieved using a single GaN transistor full-bridge inverter (i.e., without paralleled transistors).

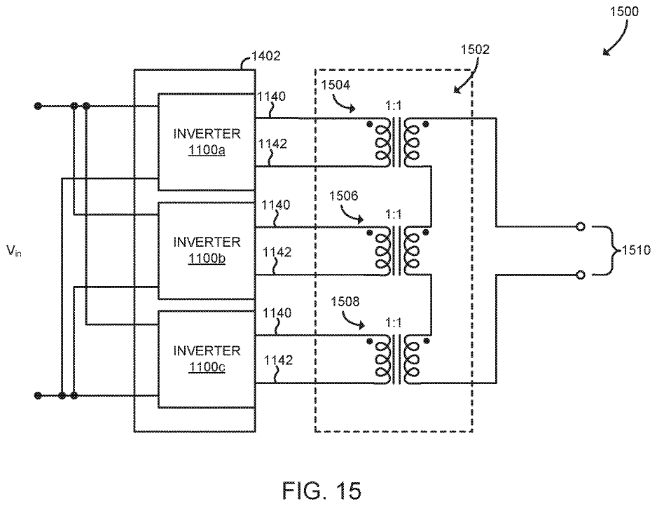

Referring now to FIG. 14, an illustrative device 1400 for high-power switching with symmetric parallel electronics devices is shown in a top view. The illustrative device 1400 includes a printed circuit board (PCB) 1402 with a top surface 1404 and a bottom surface 1406, similar to the substrate 102 of FIGS. 1-2, the PCB 302 of FIGS. 3-5, and the PCB 1102 of FIGS. 11-12. The illustrative PCB 1402 includes three instantiations of the full-bridge inverter device 1100 of FIGS. 11-12, labeled as inverters 1100a, 1100b, 1100c. Accordingly, the PCB 1402 includes a symmetric layout of electronics devices and conductive traces on both the top surface 1404 and the bottom surface 1406, as described above. One or more of the devices 1400 may be used with a high-power input source in high-power applications such as wireless power transfer (WPT) systems. In an illustrative embodiment, one or more of the devices 1400 may be used with a power combining network as shown in FIG. 15 and described below.

Referring now to FIG. 15, schematic diagram 1500 illustrates a power combining network 1502 that is connected to a PCB 1402 as shown in FIG. 14 and described above. As described above, the PCB 1402 includes three inverters 1100a, 1100b, 1100c. Each of the inverters 1100a, 1100b, 1100c is coupled to a DC input voltage Vᵢₙ, which is illustratively 300 V.

The power combining network 1502 illustratively includes three transformers 1504, 1506, 1508. Each of the transformers 1504, 1506, 1508 is illustratively an air-core transformer with a 1:1 winding ration between the primary and secondary windings. As shown, the transformers 1504, 1506, 1508 are connected to the inverters 1100a, 1100b, 1100c in a parallel-in, series-out configuration. In other words, and as shown, the respective outputs 1140, 1442 of each of the inverters 1100a, 1100b, 1100c are coupled to the primary winding of a respective transformer 1504, 1506, 1508. The secondary windings of the transformers 1504, 1506, 1508 are connected in series. An output 1510 of the power combining network may be connected to a load, such as a WPT system. In some embodiments, a similar network may be included on the other side of the load, for example as a power distribution system to one or more rectifiers or other components. Although illustrated in FIG. 15 as including a single board 1402 connected to the power combining network 1502, it should be understood that in some embodiments, multiple boards 1402 (each including multiple inverters 1100) may be connected to a power combining network with a similar parallel-in, series out transformer configuration.

For example, in an experiment, the illustrative device 1400 was used with a large air-gap capacitive wireless power transfer (WPT) system. The WPT system include a 300 V input and output with a 6.78 MHz operational frequency with a 12 cm air gap between receiving and transmitting charging pads. The experimental setup included four boards 1402, thus including twelve total inverters 1100. Each of the inverters 1100 used 650-V GaN transistors directly connected in parallel as described above. Each single inverter 1100 in the experiment was capable of delivering approximately 4.2 kW of power at 6.78 MHz, and thus each board 1402 was capable of delivering approximately 12.6 kW of power at 6.78 MHz. In the experiment, the system achieved 44.3 kW of output power, achieving peak DC-DC efficiency of 85.2% and a power transfer density of 132.9 kW/m².

1. An electronic device comprising:
a substrate comprising a top surface and a bottom surface;
a first semiconductor device coupled to the top surface of the substrate; and
a second semiconductor device coupled to the bottom surface of the substrate;
wherein the substrate further comprises (i) a first layer comprising a first conductive trace electrically coupled to a first terminal of the first semiconductor device, (ii) a second layer comprising a second conductive trace electrically coupled to a first terminal of the second semiconductor device, and (iii) a plurality of through-layer vias that electrically couple the first conductive trace and the second conductive trace;
wherein the first layer and the second layer comprise planar layers stacked vertically, the first conductive trace and the second conductive trace are coextensive when viewed from above the substrate, and the first semiconductor device and the second semiconductor device are coextensive when viewed from above the substrate.

2. The electronic device of claim 1, wherein:
the first layer further comprises a third conductive trace electrically coupled to a second terminal of the first semiconductor device;
the second layer further comprises a fourth conductive trace electrically coupled to a second terminal of the second semiconductor device; and
the substrate further comprises a plurality of through-layer vias that electrically couple the third conductive trace and the fourth conductive trace;
wherein the third conductive trace and fourth conductive trace are coextensive when viewed from above the substrate.

3. The electronic device of claim 2, wherein the electronic device comprises a half-bridge inverter, and wherein the first semiconductor device and the second semiconductor device are transistors that collectively form a first switch of the half-bridge inverter.

4. The electronic device of claim 2, wherein a horizontal distance between the first semiconductor device and the second semiconductor device to the plurality of through-layer vias is determined based on a target voltage or current of the electronic device.

5. The electronic device of claim 1, wherein the first layer comprises the top surface of the substrate, and the second layer comprises the bottom surface of the substrate.

6. The electronic device of claim 5, wherein the substrate further comprises a third layer coupled between the first layer and the second layer, wherein the third layer comprises a ground plane electrically coupled to the first semiconductor device and the second semiconductor device.

7. The electronic device of claim 5, wherein the substrate further comprises:
a third layer coupled between the first layer and the second layer, wherein the third layer comprises a ground plane electrically coupled to the first semiconductor device; and
a fourth layer couped between the first layer and the second layer, wherein the fourth layer comprises a ground plane electrically coupled to the second semiconductor device.

8. The electronic device of claim 7, wherein the substrate further comprises a fifth layer and a sixth layer coupled between the third layer and the fourth layer, wherein the fifth layer and the sixth layer comprise signaling traces.

9. The electronic device of claim 1, wherein the substrate further comprises a plurality of layers coupled between the first layer and the second layer.

10. The electronic device of claim 1, wherein each of the first semiconductor device and the second semiconductor device comprises a semiconductor power electronics device.

11. The electronic device of claim 1, wherein each of the first semiconductor device and the second semiconductor device comprises a diode, a transistor, or a thyristor.

12. The electronic device of claim 1, wherein each of the first semiconductor device and the second semiconductor device comprises a GaN device, a Si device, a SiC device, a Ga₂O₃ device, an AlN device, or a diamond device.

13. The electronic device of claim 1, wherein the substrate comprises a printed circuit board (PCB), wherein each of the first layer and the second layer comprises a dielectric material, and wherein each of the first conductive trace and the second conductive trace comprises a metallic material.

14. The electronic device of claim 13, wherein the dielectric material comprises FR4 or a low-loss dielectric material.

15. The electronic device of claim 13, wherein the metallic material comprises copper, aluminum, silver, or gold.

16. The electronic device of claim 1, wherein the first layer comprises a first geometric bounds and the second layer comprises a second geometric bounds, and wherein at least 80% of the first geometric bounds match the second geometric bounds.

17. The electronic device of claim 16, wherein at least 90% of the first geometric bounds match the second geometric bounds.

18. The electronic device of claim 1, wherein the first semiconductor device is located at a first position on the substrate, wherein the first position is defined by a pair of imaginary orthogonal axes that are parallel to the top surface of the substrate, wherein the second semiconductor device is located at a second position on the substrate defined by the pair of imaginary orthogonal axes, wherein the second position is within a predetermined threshold distance from the first position.

19. The electronic device of claim 1, further comprising:
a first full-bridge inverter and a second full-bridge inverter coupled to the printed circuit board, wherein the first semiconductor device and the second semiconductor device are transistors that collectively form a first switch of the first full-bridge inverter; and
a power-combining network coupled to the printed circuit board, wherein the power-combining network comprises a first transformer and a second transformer;
wherein a primary winding of the first transformer is coupled to the first full-bridge inverter and a primary winding of the second transformer is coupled to the second full-bridge inverter; and
wherein a secondary winding of the first transformer and a secondary winding of the second transformer are coupled in series.

20. The electronic device of claim 19, wherein each of the first transformer and the second transformer are 1:1 air-core transformers.
